(19) United States
(12) Patent Application Publication
(10) Pub. No.: US 2015/0069364 A1
(43) Pub. Date: Mar. 12, 2015

(54) ORGANIC LIGHT-EMITTING DIODE DISPLAY AND METHOD OF MANUFACTURING THE SAME

(71) Applicant: TPK Touch Solutions Inc., Taipei (TW)

(72) Inventors: Chen-Yu Liu, Taoyuan (TW); Hung-Chieh Lu, Hsinchu (TW); Hsi-Chien Lin, Hsinchu (TW)

(21) Appl. No.: 14/481,865

(22) Filed: Sep. 9, 2014

(30) Foreign Application Priority Data
Sep. 9, 2013 (CN) 201310409844.7

(51) Int. Cl. H01L 27/32; H01L 51/52; H01L 51/56

(52) U.S. Cl. CPC H01L 27/3206; H01L 51/56; H01L 51/5218; H01L 51/5234
USPC 257/40; 438/29

(57) ABSTRACT

An organic light-emitting diode display and method of manufacturing the same are provided in the present invention. The organic light-emitting diode display includes an anode layer and a cathode layer opposite to and spaced apart from each other, an organic light-emitting layer disposed between the anode layer and the cathode layer, wherein the organic light-emitting layer includes primary color regions and mixed color regions, and a color deviation protective layer disposed between the anode layer and the organic light-emitting layer or between the organic light-emitting layer and the cathode layer, and the color deviation protective layer is provided with insulating patterns corresponding to the mixed color regions to prevent light generation from the mixed color regions. The manufacturing method features the step of disposing a color deviation protective layer to prevent light generation from the mixed color regions of the organic light-emitting layer and solve conventional color deviation issue.

### BACKGROUND OF THE INVENTION

This Application claims priority of China Patent Application No. CN 201310409844.7, filed on Sep. 9, 2013, and the entirety of which is incorporated by reference herein.

1. Field of the Invention

The present invention generally relates to a display, and more particularly, to an organic light-emitting diode (OLED) display and method of manufacturing the same.

2. Description of the Prior Art

The organic light-emitting diode (OLED) display is always considered as being among the most competitive technology in next display generation, with the advantages of self-luminous (does not need a backlight unit), fast response, and low operating voltage.

A standard OLED display is self-luminous with an organic material layer formed of organic materials. When a current is applied on the organic material layer, the organic material in the organic material layer emits light. With different organic materials, the OLED display may emit light with different colors, to fulfill the requirement of full color display.

Currently, an evaporation tool is utilized to form the organic material layer with red(R), green(G) and blue(B) colors in the manufacture of the OLED displays. The evaporation tool has a tension mask with openings to define pixel areas on the organic material layer. During the evaporation process, the organic material with one of the R, G, B colors is first deposited on a pixel area through the openings of the tension mask. The tension mask is then moved to other pixel area and forms the organic materials with other color (ex. G and B) through the same openings. Since the organic material would leave residue on the tension mask near the openings during the evaporation process, the weight of the organic materials would cause the deformation of the tension mask and change the original shape of the openings on the tension mask, so that the openings of the tension mask can't be precisely aligned in the process and results in mixed color regions on the organic material layer. That is, a pixel area is formed with stacked different colors, thereby causing the color deviation issue.

### BRIEF SUMMARY OF THE DISCLOURE

In view of the above-mentioned issue, an approach of disposing a color deviation protective layer in the organic light-emitting diode (OLED) display is utilized in the present invention to prevent the mixed color regions of the organic light-emitting layer from emitting light, thereby solving the conventional color deviation issue.

An OLED display is provided in the present invention, including an anode layer and a cathode layer opposite to and spaced apart from each other, an organic light-emitting layer disposed between the anode layer and the cathode layer, wherein the organic light-emitting layer includes primary color regions and mixed color regions, and a color deviation protective layer disposed between the anode layer and the organic light-emitting layer or between the organic light-emitting layer and the cathode layer, and the color deviation protective layer is provided with insulating patterns corresponding to the mixed color regions, wherein the insulating patterns is used to prevent the corresponding mixed color regions from emitting light.

A method of manufacturing an OLED display is provided in the present invention, including the steps of disposing an anode layer and a cathode layer opposite to and spaced apart from each other, disposing an organic light-emitting layer between the cathode layer and the anode layer, wherein the organic light-emitting layer includes primary color regions and mixed color regions, and disposing an color deviation protective layer between the anode layer and the organic light-emitting layer or between the organic light-emitting layer and the cathode layer, and the color deviation protective layer is provided with insulating patterns corresponding to the mixed color regions, wherein the insulating pattern is used to prevent the mixing color regions from emitting light.

The approach of disposing a color deviation protective layer in the OLED display is utilized in the present invention to prevent the mixed color regions of the organic light-emitting layer from emitting light, thereby solving the conventional color deviation issue and significantly increase the production yield.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are cross-sectional views schematically showing a process flow of an OLED display in accordance with one preferred embodiment of the present invention; and

FIGS. 5-9 are cross-sectional views schematically showing a variety of types of the OLED display of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### Description of the Exemplary Embodiments

In the following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims. Besides, the terms “on” or “under” (“above” or “below”) referred in the following embodiments are used to describe relative positions between components rather than limiting the scope of the present invention.

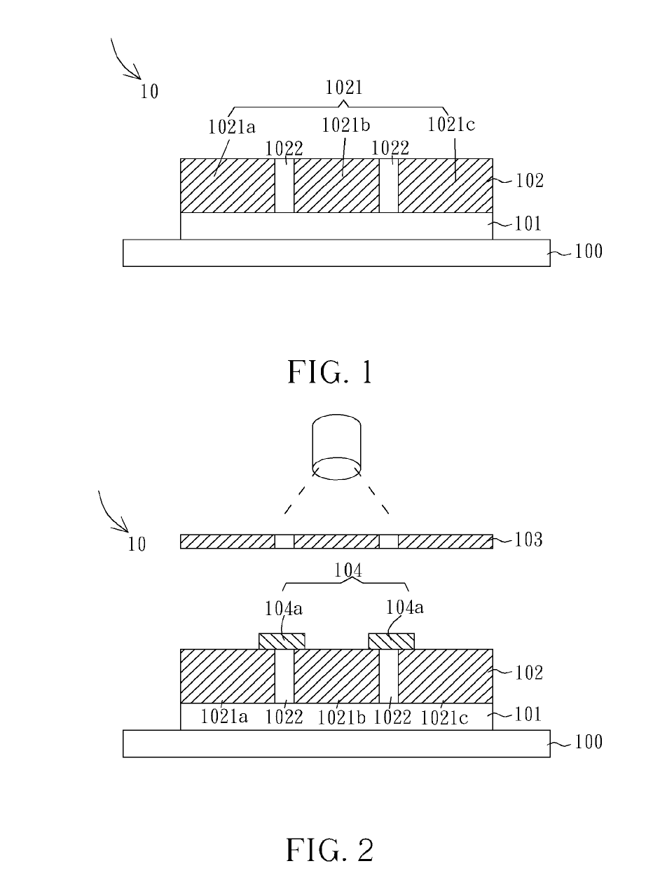

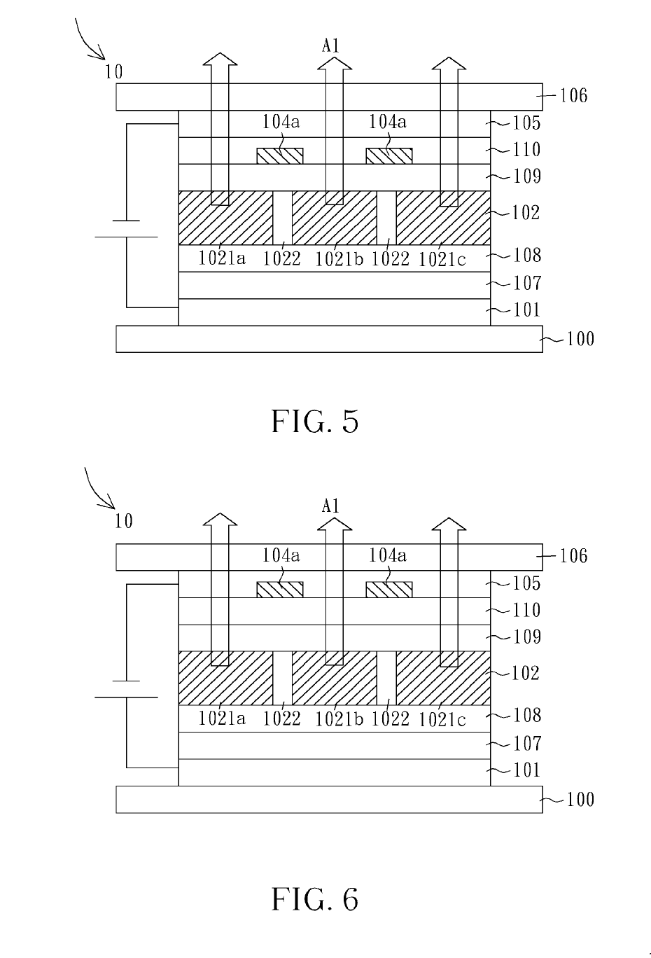

Several embodiments are provided hereinafter accompanying the figures to describe the skill of the present invention, wherein FIGS. 1-4 are cross-sectional views schematically showing a process flow of manufacturing an OLED display according to one preferred embodiment of the present invention, and FIGS. 5-9 are cross-sectional views schematically showing a variety of types of the OLED display of the present invention.

The method of manufacturing an OLED display in the present invention includes the steps of disposing an anode layer and a cathode layer opposite to and spaced apart from each other, disposing an organic light-emitting layer between the cathode layer and the anode layer, wherein the organic light-emitting layer includes primary color regions and mixed color regions, and disposing a color deviation protective layer between the anode layer and the organic light-emitting layer or between the organic light-emitting layer and the cathode layer, and the color deviation protective layer is provided with insulating patterns corresponding to the mixed color regions to prevent light generation from the mixed color regions.

In one embodiment, an upper substrate and a lower substrate are further provided before the organic light-emitting layer is disposed, and the anode layer and the cathode layer are disposed between the upper substrate and the lower substrate.

The flow of manufacturing the OLED display will be explained in detail in the following embodiments with reference to the accompanying figures.

Please note that, in this embodiment, the OLED display is top-emitting display, which means the light of the OLED display is emitted out from the upper substrate. In other embodiments, the OLED display can be bottom-emitting display, in other words, the light of OLED display is emitted out from the lower substrate.

Please refer to FIG. 1. In the beginning, a lower substrate 100 is provided as a base for all components, for example, the lower substrate 100 may be a transparent glass plate or plastic plate or other material which may support the components, in addition, the lower substrate 100 may be a reinforced plate. An anode layer 101 is then formed above or on the upper surface of the lower substrate 100 by evaporation or sputtering process. The material of the anode layer 101 may be transparent conducting oxide (TCO), such as indium tin oxide (ITO), zinc oxide (ZnO), Al:ZnO (AZO), or opaque metals, such as Ni, Au, Mo, or Pt, etc.

After the anode layer 101 is formed, an organic light-emitting layer (EML) 102 is formed on the anode layer 101. The organic light-emitting layer 102 includes primary color regions 1021, for example, red primary color regions 1021a, green primary color regions 1021b and blue primary color regions 1021c. The material of primary color regions 1021 of the organic light-emitting layer 102 may be different depending on the colors of the primary color regions 1021, for example, uses red dyes of DCM(4-(Dicyanomethylene)-2-methyl-6-(4-dimethylaminostyryl)-4H-pyran),DCM-2, or DCJTB(4-(Dicyanomethylene)-2-tert-butyl-6-(1,1,7,7-tetra methyljulolidin-4-yl-vinyl)-4H-pyran) for red primary color region 1021a, uses green dyes of Alq((8-hydroxyquinoline)aluminum), Alq3(tris-(8-hydroxyquinoline)aluminum), or DMQA(N,N′-Dimethyl-quinacridone) for green primary color regions, and uses anthracene, Alq2, BCzVBi(4,4″-bis(9-ethyl-3-carbazovinylene)-1,1″-biphenyl), Perylene, OXD(oxadiazole), DPVB(Bis(2,2-diphenylvinyl)benzene) for blue primary color regions. The organic light-emitting layer 102 may be formed by using a conventional evaporation tool and corresponding tension mask to deposit red, green and blue color emitting materials to respectively form red primary color regions 1021a, green primary color regions 1021b and blue primary color regions 1021c. Since the organic material would leave residue on the tension mask near the openings during the evaporation process, the weight of the organic materials would cause the deformation of the tension mask and change the original shape of the openings on the tension mask, so that the openings of the tension mask can't be precisely aligned in the process and results in mixed color regions 1022 on the organic material layer 102.

Please refer to FIG. 2, a mask 103 is disposed above or below (disposed above in this embodiment) the organic light-emitting layer 102 after the organic light-emitting layer 102 is formed. An evaporation process or sputtering process is then performed through the mask 103 to form color deviation protective layer 104 on the organic light-emitting layer 102, wherein the color deviation protective layer 104 is provided with insulating patterns 104a corresponding to the mixed color regions 1022. The material of the insulating pattern 104a may be silicon dioxide or photoresist.

If the material of the insulating pattern 104a is photoresist, a photoresist layer is first coated and the photolithographic process and etching process (including the steps of UV exposure and development, etc) are then performed to pattern the photoresist layer and form the insulating patterns 104a. Alternatively, the photoresist layer may be formed first by sputtering process on the organic light-emitting layer 102, then the photolithographic and etching processes are performed to pattern the photoresist layer and form the insulating patterns 104a.

In one preferred embodiment, the insulating patterns 104a may be formed of silicon dioxide. In addition, the insulating patterns 104a may be formed by using the same photolithographic and etching processes, and thus is not repeatedly described herein.

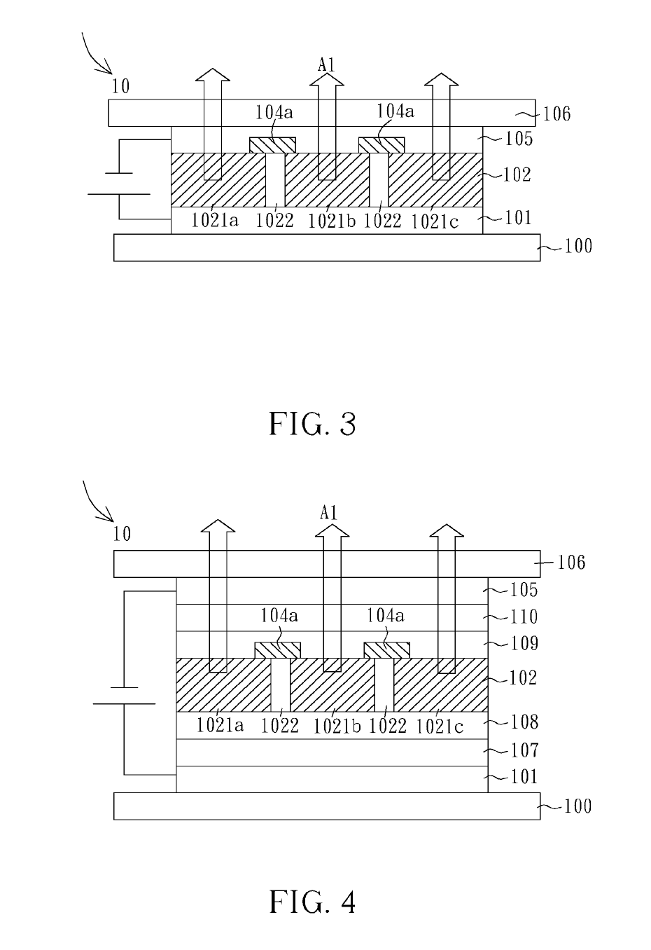

Please refer to FIG. 3, a cathode layer 105 is then formed on the color deviation protective layer 104. The function of the cathode layer 105 is to generate electrons, thus metal materials with low work function are generally utilized, such as alkali, alkaline earth or lanthanide materials with low work function. Afterward, an upper substrate 106 is provided on the cathode layer 105 to protect the whole components. The upper substrate 106 may be a transparent glass plate, plastic plate or other material which may support the components. The main process of making the structure of the OLED display 10 is therefore completed.

As shown in FIG. 3, when a current is applied, holes generated from the anode layer 101 and electrons generated from the cathode layer 105 would combine in the organic light-emitting layer 102 to generate photons and emit light from the organic light-emitting layer 102. However, in the present invention, the holes generated from the anode layer 101 and the electrons generated from the cathode layer 105 can not combine in the mixed color regions 1022 to form photons due to the insulating patterns 104a disposed on corresponding mixed color regions 1022, thereby inhibiting light emitted from the mixed color regions 1022 and preventing the color deviation issue.

It should be noted that the direction of light emitted from the OLED display may be different depending on the selected materials of the anode layer 101 and the cathode layer 105.

In one embodiment, the anode layer 101 may be an aluminum layer with a thickness of 150 nm to 200 nm or a gold layer with a thickness of 100 nm to 150 nm, and the cathode layer 105 may be an aluminum layer with a thickness of 0.1 nm to 20 nm, a silver layer with a thickness of 0.1 nm to 20 nm, or an ITO layer or IZO layer with a thickness of 20 nm to 100 nm. In this embodiment, the anode layer 101 is light-reflective type, and the cathode layer 105 is light-transparent type. The light of the OLED display 10 is emitted upward along the direction Al and to the upper substrate 106.

In another embodiment, the anode layer 101 may be ITO layer or IZO layer with a thickness of 50 nm to 300 nm, and the cathode layer 105 may be an aluminum layer with a thickness of 150 μm to 200 μm. In this embodiment, the anode layer 101 is light-transparent type, and the cathode layer 105 is light-reflective type. The light may be emitted downwardly from the OLED display 10 to the lower substrate 100.

In the embodiment above, the color deviation protective layer 104 is disposed between the cathode layer 105 and the organic light-emitting layer 102. In other embodiments, the color deviation protective layer 104 may be disposed between the anode layer 101 and the organic light-emitting layer 102.

In the above embodiment, other layer structures may be added to the OLED display 10 to improve the emitting efficiency of the OLED display.

Please refer to FIG. 4. In this embodiment, the anode layer 101 is formed on the lower substrate 100. A hole injection layer 107 is formed on the anode layer 101. The hole injection layer 107 may be formed of the material with the highest occupied molecular orbital (HOMO) energy level and the material with work function matching the anode layer 101, such as CuPc (copper phthalocyanine), TiOPc, m-MTDATA(4,4′,4″-tris(3-methylphenylphenylamino)triphenylamine), 2-TNATA (4,4′A″-tris(2-naphthylphenylamino)triphenylamine) or PEDOT-PSS (poly(3,4-ethylene dioxythiophene)-poly(styrenesulfonate)), etc. The hole injection layer 107 may be formed through the process such as evaporation, spin coating, or blade coating, etc. The function of the hole injection layer 107 is to increase the charge injection so as to increase the emitting efficiency of the OLED display 10.

After the hole injection layer 107 is formed, a hole transport layer (HTL) 108 is formed on the hole injection layer 107 by the process such as evaporation, spin coating or blade coating, etc. The hole transport layer 108 may be formed of thin film materials with high hole mobility and high thermal stability, for example, NPB (naphtha-phenylene benzidine), TPD(N,N′-diphenyl-N,N′-di(3-methylphenyl)-1,1′-biphenyl-4,4′-diamine), or PVK (poly(9-vinyl carbazole)), etc. The function of the hole transport layer 108 is to increase the hole transport rate, so as to increase the emitting efficiency of the OLED display 10.

After the hole transport layer 108 is formed, the organic light-emitting layer 102 is formed on the hole transport layer 108. The organic light-emitting layer 102 is provided with primary color regions 1021 and mixed color regions 1022. A color deviation protective layer 104 (not shown in FIG. 4) is then formed on the organic light-emitting layer 102, wherein the color deviation protective layer 104 is provided with insulating patterns 104a corresponding to the mixed color regions 1022. An electron transport layer (ETL) 109 may be then formed on the color deviation protective layer 104. The function of electron transport layer 109 is to facilitate the transportation of the injected electrons from the cathode layer 105 to the organic light-emitting layer 102, so as to inhibit the transition of the holes to the cathode layer 105. For this reason, the material of electron transport layer 109 must have high electron mobility with enough barrier level to block the hole, such as the materials of PBD(2-(4-biphenyl)-5-(4-tert-butylphenyl)-1,3,4-oxadiazole), OXD, TAZ(3-(biphenyl4-yl)-4-phenyl-5-(4-tert-butylphenyl)-4H-1,2,4-triazole) or Alq3, formed on the color deviation protective layer 104 by evaporation, spin coating or blade coating, etc.

An electron injection layer (EIL) 110 is formed on the electron transport layer 109 to facilitate the electron injection, which may be formed of the material with lowest unoccupied molecular orbital (LUMO) energy level and the material with work function matching the cathode layer 105, such as LiF, LiO₃, LiBO₂, etc. A cathode layer 105 is then formed on the electron injection layer 110, and an upper substrate 106 is finally provided on the cathode layer 105 to protect the whole components, such as a transparent glass plate or plastic or other materials which may support the components. The main process of making the structure of the OLED display 10 is therefore completed.

In one embodiment, the main structure of the OLED display 10 is shown in FIG. 3. The anode layer 101 of the OLED display is light-reflective type, while the cathode layer 110 is light-transparent type, thus the light emitted from the OLED display 10 would travel upward through the upper substrate 106 along the direction Al. The whole stack structure from bottom up includes the lower substrate 100, the anode layer 101, the organic light-emitting layer 102 with primary color regions 1021 and mixed color regions 1022, the color deviation protective layer 104 with insulating patterns 104a corresponding to the mixed color regions 1022, the cathode layer 105 and the upper substrate 106.

In another embodiment, the main structure of the OLED display 10 is shown like FIG. 4. The anode layer 101 of the OLED display is light-reflective type, while the cathode layer 110 is light-transparent type, thus the light emitted from the OLED display 10 would travel upward through the upper substrate 106 along the direction Al. The whole stack structure from bottom up includes the lower substrate 100, the anode layer 101, the hole transport layer 108, the organic light-emitting layer 102 with primary color regions 1021 and mixed color regions 1022, the color deviation protective layer 104 with insulating patterns 104a corresponding to the mixed color regions 1022, the electron transport layer 109, the electron injection layer 110, the cathode layer 105 and the upper substrate 106.

The structure shown in the above embodiment is merely an exemplary configuration of the present invention. In another embodiment, the color deviation protective layer 104 may be disposed in different positions depending on the light-emitting directions of the OLED display 10, as long as it corresponds to the mixed color regions 1022. Please refer to FIGS. 5-9, which are cross-sectional views schematically showing a variety of types of the OLED display 10 of the present invention.

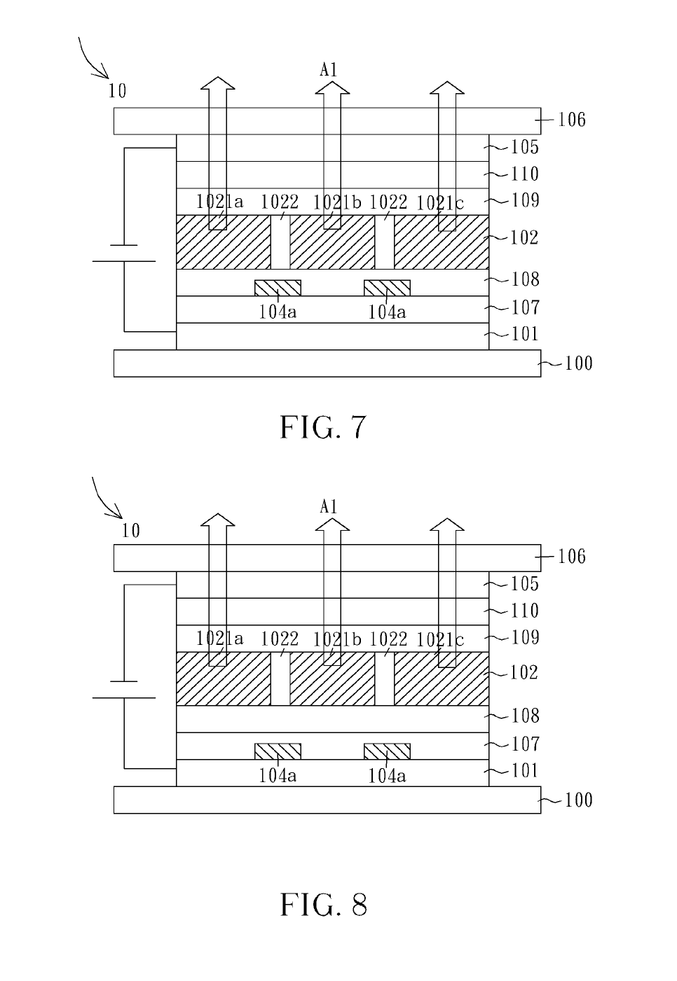

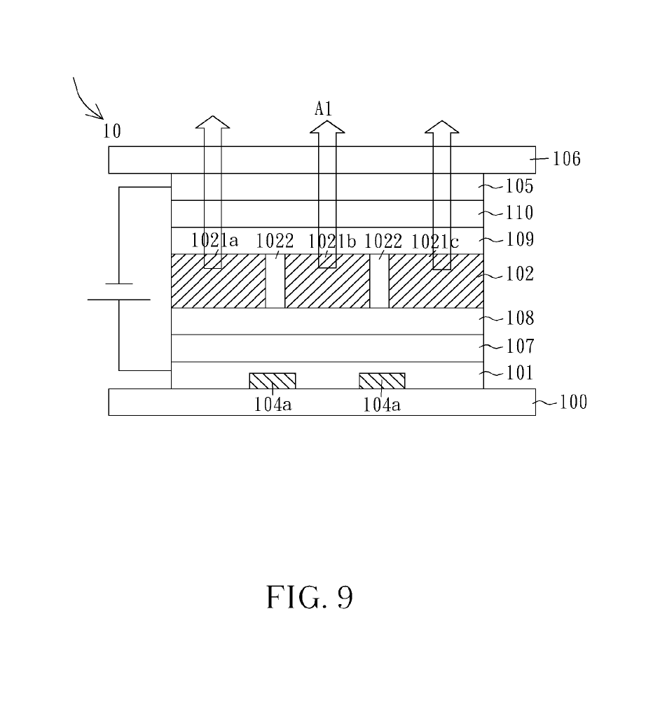

In one embodiment, the color deviation protective layer 104 may be disposed between the electron transport layer 109 and the electron injection layer 110 (FIG. 5), between the electron injection layer 110 and the cathode layer 105 (FIG. 6), between the hole transport layer 108 and the hole injection layer 107 (FIG. 7), between the hole injection layer 107 and the anode layer 101 (FIG. 8), or between the anode layer 101 and the lower substrate 100 (FIG. 9), to achieve the function of inhibiting the combination of holes and electrons in the mixed color regions 1022 and preventing the color deviation issue.

In the present invention, the shape of the color deviation protective layer 104 is not limited to squares as shown in the figures. Rhombus, trapezoid, and funnel-shape are within the scope of the present invention, as long as the color deviation protective layer 104 can completely block the mixed color regions 1022.

It should be noted that the light-emitting direction, whether upwardly or downwardly, of the OLED display 10 are not limited in the present invention, and the position of the color deviation protective layer 104 is not limited by the light-emitting direction of the OLED display 10. The only requirement is the color deviation protective layer 104 being disposed between the anode layer 101 and the cathode layer 105 to inhibit the combination of holes and electrons and the light generation in the mixed color regions 1022 of the organic light-emitting layer 102, so as to prevent the color deviation issue and significantly increase the production yield.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic light-emitting diode display, comprising:
an anode layer;
a cathode layer opposite to and spaced apart from said anode layer;
an organic light-emitting layer disposed between said anode layer and said cathode layer, wherein said organic light-emitting layer comprises primary color regions and mixed color regions; and
an color deviation protective layer disposed between said anode layer and said organic light-emitting layer or between said organic light-emitting layer and said cathode layer, and said color deviation protective layer is provided with insulating patterns corresponding to said mixed color regions, wherein said insulating patterns are used to prevent the light generation from said corresponding mixed color regions.

2. The organic light-emitting diode display according to claim 1, wherein said organic light-emitting diode display further comprises:
an upper substrate and a lower substrate, wherein said cathode layer and said anode layer are disposed between said upper substrate and said lower substrate.

3. The organic light-emitting diode display according to claim 2, wherein said anode layer is light-reflective type and said cathode is light-transparent type, and the light of said organic light-emitting diode display is emitted out from said upper substrate.

4. The organic light-emitting diode display according to claim 3, wherein said light-reflective type anode layer is an aluminum layer with a thickness of 150 nm to 200 nm or a gold layer with a thickness of 100 nm to 150 nm, and said light-transparent type cathode layer is an aluminum layer with a thickness of 0.1 nm to 20 nm, or an indium tin oxide (ITO) layer or indium zinc oxide (IZO) layer with a thickness of 20 nm to 100 nm.

5. The organic light-emitting diode display according to claim 2, wherein said anode layer is light-transparent type and said cathode layer is light-reflective type, and the light of said organic light-emitting diode display is emitted out from said lower substrate.

6. The organic light-emitting diode display according to claim 5, wherein said light-transparent type anode layer is an indium tin oxide (ITO) layer or an indium zinc oxide (IZO) layer with a thickness of 50 nm to 300 nm, and said light-reflective type cathode layer is an aluminum layer with a thickness of 150 μm to 200 μm.

7. The organic light-emitting diode display according to claim 1, wherein the material of said insulating pattern is photoresist or silicon dioxide.

8. A method of manufacturing an organic light-emitting diode display, comprising:
disposing an anode layer;
disposing a cathode layer, wherein said anode layer and said cathode layer are opposite to and spaced apart from each other;
disposing an organic light-emitting layer between said cathode layer and said anode layer, wherein said organic light-emitting layer comprises primary color regions and mixed color regions; and
disposing an color deviation protective layer between said anode layer and said organic light-emitting layer or between said organic light-emitting layer and said cathode layer, and said color deviation protective layer is provided with insulating patterns corresponding to said mixed color regions, wherein said insulating pattern is used to prevent light generation from said mixed color regions.

9. The method of manufacturing an organic light-emitting diode display according to claim 8, further comprising providing an upper substrate and a lower substrate, wherein said cathode layer and said anode layer are disposed between said upper substrate and said lower substrate.

10. The method of manufacturing an organic light-emitting diode display according to claim 9, wherein said anode layer is light-reflective type and said cathode layer is light-transparent type, and the light of said organic light-emitting diode display is emitted out from said upper substrate.

11. The method of manufacturing an organic light-emitting diode display according to claim 9, wherein said anode layer is light-transparent type and said cathode is light-reflective type, and the light of said organic light-emitting diode display is emitted out from said lower substrate.

12. The method of manufacturing an organic light-emitting diode display according to claim 8, wherein the material of said insulating pattern is photoresist or silicon dioxide.

13. The method of manufacturing an organic light-emitting diode display according to claim 8, wherein the step of forming said insulating patterns comprises:
coating a photoresist layer; and
patterning said photoresist layer by a photolithographic process and an etching process to form said insulating patterns.

14. The method of manufacturing an organic light-emitting diode display according to claim 8, wherein the step of forming said insulating patterns comprises:
evaporating or sputtering silicon dioxide to form said insulating patterns.
